(19) United States
(12) Patent Application Publication
(10) Pub. No.: US 2014/0175266 A1
(43) Pub. Date: Jun. 26, 2014

(54) CIRCUIT BOARD ASSEMBLY EMPLOYED IN OPTICAL CONNECTOR

(71) Applicant: HON HAI PRECISION INDUSTRY CO., LTD., New Taipei (TW)

(72) Inventor: KAI-WEN WU, New Taipei (TW)

(73) Assignee: HON HAI PRECISION INDUSTRY CO., LTD., New Taipei (TW)

(21) Appl. No.: 13/757,061

(22) Filed: Feb. 1, 2013

(30) Foreign Application Priority Data
Dec. 26, 2012 (TW) 101150014

(51) Int. Cl. H01L 25/16

(52) U.S. Cl. CPC H01L 25/167
USPC 250/208.2

(57) ABSTRACT

A circuit board assembly includes a printed circuit board (PCB), at least two laser diodes, a number of first bonding wires, at least two photo diodes and a number of second bonding wires. The PCB includes a mounting surface, a first connecting pad, and a second connecting pad, both the first connecting pad and the second connecting pad are positioned on the mounting surface. The at least two laser diodes and the driving chip mounted on the first connecting pad. The first bonding wires each electrically connects the laser diodes to the driving chip. The photo diodes and the transimpedance amplifier mounted on the second connecting pad. The second bonding wires each electrically connects the photo diodes to the transimpedance amplifier.

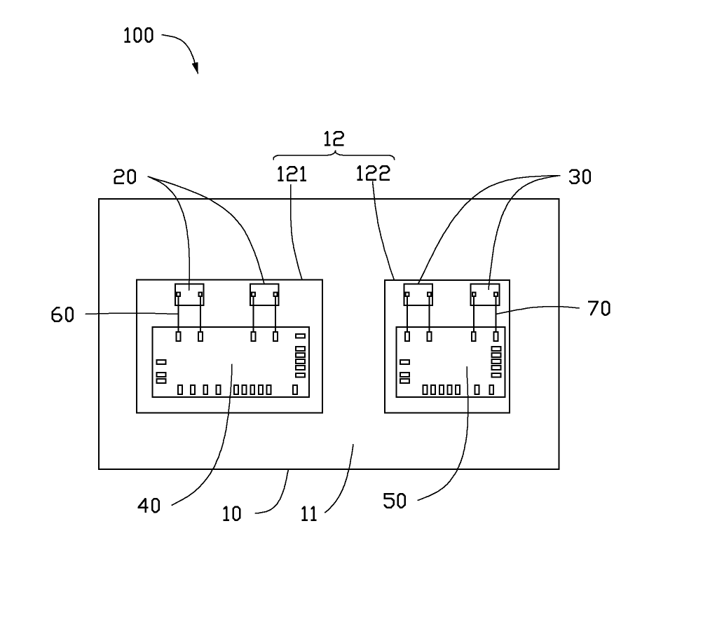

### BACKGROUND

1. Technical Field

The present disclosure relates to circuit board assemblies, and particularly to a circuit board assembly employed in an optical connector.

2. Description of Related Art

Optical connectors include a circuit board, two laser diodes, two photo diodes, a driving chip and a transimpedance amplifier. The circuit board forms a number of connecting pads. The laser diodes, the photo diodes, the driving chip and the transimpedance amplifier are respectively positioned on a corresponding connecting pad. This will increase a distance between the laser diodes and the driving chip, and increase a distance between the photo diodes and the transimpedance amplifier.

To achieve predetermined functions, bonding wires are utilized to electrically connect the laser diodes to the driving chip, and connect the photo diodes to the transimpedance amplifier, to transmit high-frequency signals between the laser diodes and the driving chip, and transmit high-frequency signals between the photo diodes and the transimpedance amplifier. However, a large inductance is introduced and increases signal loss at the bonding wires when transmitting the high-frequency signals.

What is needed therefore is a circuit board assembly which can overcome the above-mentioned limitations.

### BRIEF DESCRIPTION OF THE DRAWINGS

The components of the drawings are not necessarily drawn to scale, the emphasis instead being placed upon clearly illustrating the principles of the embodiments of the present disclosure. Moreover, in the drawings, like reference numerals designate corresponding parts throughout several views.

The figure is a schematic view of a circuit board assembly employed in an optical connector, according to an exemplary embodiment.

### DETAILED DESCRIPTION

The figure shows a circuit board assembly 100, according to an embodiment. The chip assembly 100 can be employed in an optical connector (not shown). The circuit board assembly 100 includes a printed circuit board (PCB) 10, two laser diodes 20, two photo diodes 30, a driving chip 40 and a transimpedance amplifier 50. The two laser diodes 20, the two photo diodes chip 30, the driving chip 40 and the transimpedance amplifier 50 are positioned on the PCB 10.

The PCB 10 includes a mounting surface 11. The mounting surface 11 is substantially rectangular-shaped. The PCB 10 includes two connecting pads 12, such as a first connecting pad 121 and a second connecting pad 122, positioned on the mounting surface 11. The PCB 10 contains various circuits (not shown) that connect with the first connecting pad 121 and the second connecting pad 122.

Both the first connecting pad 121 and the second connecting pad 122 are made of metal. In the embodiment, both the first connecting pad 121 and the second connecting pad 122 are made of copper. Both the first connecting pad 121 and the second connecting pad 122 are also substantially rectangular-shaped. A total size of the first connecting pad 121 and the second connecting pad 122 is smaller than a size of the mounting surface 11 of the PCB 10.

Both the laser diode 20 and the driving chip 40 are also substantially rectangular-shaped. A total size of the two laser diodes 20 and the driving chip 40 is smaller than the size of the first connecting pad 121. As such, the two laser diodes 20 and the driving chip 40 are mounted on the first connecting pad 121. Both the two laser diodes 20 are substantially parallel with the driving chip 40. In the embodiment, a distance between one of the laser diodes 20 and the driving chip 40 is 4 mils, a distance between the other laser diode 20 and the driving chip 40 is also 4 mils.

The circuit board assembly 100 further includes a number of first bonding wires 60. The first bonding wires 60 each electrically connect the laser diodes 20 to the driving chip 40, as such the laser diodes 20 are electrically connected to the driving chip 40. The driving chip 40 is configured to drive the two laser diodes 20 to emit laser beam coupled into two optical fibers (not shown) through two coupling lenses (not shown). The first bonding wires 60 are made from a material(s) with high conductivity. In the embodiment, the first bonding wires 60 are made from gold. The two laser diodes 20 are electrically connected to the driving chip 40 through four first bonding wires 60, and the four first bonding wires 60 are substantially parallel with each other.

Both the photo diodes 30 and the transimpedance amplifier 50 are also substantially rectangular-shaped. A total size of the two photo diodes 30 and the transimpedance amplifier 50 is smaller than the size of the second connecting pad 122. As such, the two photo diodes 30 and the transimpedance amplifier 50 are mounted on the second connecting pad 122. Both the two photo diodes 30 are substantially parallel with the transimpedance amplifier 50. In the embodiment, a distance between one of the photo diodes 30 and the transimpedance amplifier 50 is 4 mils, and a distance between the other photo diode 30 and the transimpedance amplifier 50 is also 4 mils.

The circuit board assembly 100 further includes a number of second bonding wires 70. The second bonding wires 70 each electrically connect the photo diodes 30 to the transimpedance amplifier 50, as such the photo diodes 30 are electrically connected to the transimpedance amplifier 50. The photo diodes 30 are configured to receive laser beam transformed from two optical fibers (not shown) and general a current corresponding to the laser beam. The transimpedance amplifier 50 is configured to the current generated by the photo diodes 30 into a voltage signal for further amplification. The second bonding wires 70 are also made from a material(s) with high conductivity. In the embodiment, the second bonding wires 70 are made from gold. The two photo diodes 30 are electrically connected to the transimpedance amplifier 50 through four second bonding wires 70, and the four second bonding wires 70 are substantially parallel with each other.

In other embodiments, the numbers of the laser diodes 20, the photo diodes 30, can be changed depending on need.

In other embodiments, the shapes of the first connecting pad 121 and the second connecting pad 122 can be changed depending on need.

It will be understood that the above particular embodiments are shown and described by way of illustration only. The principles and the features of the present disclosure may be employed in various and numerous embodiment thereof without departing from the scope of the disclosure as claimed. The above-described embodiments illustrate the possible scope of the disclosure but do not restrict the scope of the disclosure.

What is claimed is:

1. A circuit board assembly, comprising:
a printed circuit board (PCB) comprising a mounting surface, a first connecting pad and a second connecting pad, both the first connecting pad and the second connecting pad positioned on the mounting surface;
at least two laser diodes;
a driving chip, a total size of the at least two laser diodes and the driving chip being smaller than a size of the first connecting pad, the at least two laser diodes and the driving chip mounted on the first connecting pad;
a plurality of first bonding wires, the first bonding wires each electrically connecting each laser diode to the driving chip;
at least two photo diodes;
a transimpedance amplifier, a total size of the at least two photo diodes and the transimpedance amplifier being smaller than a size of the second connecting pad, the at least two photo diodes and the transimpedance amplifier mounted on the second connecting pad; and
a plurality of second bonding wires, the second bonding wires each electrically connecting each photo diode to the transimpedance amplifier.

2. The circuit board assembly of claim 1, wherein both the first connecting pad and the second connecting pad are made of metal.

3. The circuit board assembly of claim 2, wherein both the first connecting pad and the second connecting pad are made of copper.

4. The circuit board assembly of claim 1, wherein the mounting surface is substantially rectangular-shaped, both the first connecting pad and the second connecting pad are also substantially rectangular-shaped.

5. The circuit board assembly of claim 4, wherein the at least two laser diodes and the driving chip are also substantially rectangular-shaped.

6. The circuit board assembly of claim 4, wherein the at least two photo diodes and the transimpedance amplifier are also substantially rectangular-shaped.

7. The circuit board assembly of claim 1, wherein the at least two laser diodes are substantially parallel with the driving chip.

8. The circuit board assembly of claim 7, wherein a distance between each laser diode and the driving chip is 4 mils.

9. The circuit board assembly of claim 7, wherein the plurality of the first bonding wires are substantially parallel with each other.

10. The circuit board assembly of claim 1, wherein the at least two photo diodes are substantially parallel with the transimpedance amplifier.

11. The circuit board assembly of claim 10, wherein a distance between each photo diode and the transimpedance amplifier is 4 mils.

12. The circuit board assembly of claim 10, wherein the plurality of the second bonding wires are substantially parallel with each other.

13. The circuit board assembly of claim 1, wherein the first bonding wires and the second bonding wires are made from a material with high conductivity.

14. The circuit board assembly of claim 13, wherein the first bonding wires and the second bonding wires are made from gold.

15. The circuit board assembly of claim 1, wherein a total size of the first connecting pad and the second connecting pad is smaller than a size of the mounting surface.

16. The circuit board assembly of claim 1, wherein the driving chip is configured to drive the at least two laser diodes to emit laser beams.

17. The circuit board assembly of claim 1, wherein the at least two photo diodes are configured to receive laser beams and generate currents corresponding to the laser beams, the transimpedance amplifier is configured to convert the currents generated by the at least two photo diodes into voltage signals for further amplification.
